(19) United States
(12) Patent Application Publication
(10) Pub. No.: US 2017/0190856 A1
(43) Pub. Date: Jul. 6, 2017

(54) PROCESS FOR PREPARING A COMPOSITE PART THAT IS ELECTRICALLY CONDUCTIVE AT THE SURFACE, AND APPLICATIONS

(71) Applicants: CENTRE NATIONAL DE LA RECHERCHE SCIENTIFIQUE, PARIS (FR); UNIVERSITE PAUL SABATIER - TOULOUSE III, Toulouse cedex 9 (FR)

(72) Inventors: Antoine LONJON, TOULOUSE (FR); Eric DANTRAS, TOULOUSE (FR); Colette LACABANNE, TOULOUSE (FR)

(21) Appl. No.: 15/129,251

(22) PCT Filed: Mar. 25, 2015
(86) PCT No.: PCT/FR2015/050744

§ 371 Date: Sep. 26, 2016

(30) Foreign Application Priority Data
Mar. 27, 2014 (FR) 1452641

(51) Int. Cl. C08J 7/04; H05K 5/04; C25D 5/56; H05K 9/00; C09D 5/24; C25D 3/12

(52) U.S. Cl. CPC C08J 7/045; C09D 5/24; C25D 3/12; C25D 5/56; H05K 9/0088; H05K 5/04; C08J 2363/00; C08J 2463/00; C08J 2475/04; C08J 2381/02; C08J 2371/10

(57) ABSTRACT

A process is provided for preparing a high-performance composite part that is electrically conductive at the surface. The process is used for improving the resistance of an electrically insulating part to rubbing, wear, and harsh atmospheric and/or chemical conditions, and to ensure the protection of an electrically insulating part against electromagnetic radiation (electromagnetic shielding) and/or against electrostatic discharges. The process improves the surface electrical conductivity of a material.

The invention relates to a process for preparing a high-performance composite part that is electrically conductive at the surface, to said high-performance composite part that is electrically conductive at the surface, to the use of said high-performance composite part that is electrically conductive at the surface in housings for electrical and electronic components, to the use of said process for improving the abrasion resistance, wear resistance and resistance to harsh atmospheric and/or chemical conditions of an electrically insulating part, to the use of said process for ensuring the protection of an electrically insulating part against electromagnetic radiation (electromagnetic shielding) and/or against electrostatic discharges, and to the use of said process for improving the surface electrical conductivity of a material.

The present invention applies typically, but not exclusively, to the motor vehicle, aeronautical, aerospace (e.g. electronic satellites), computer and electronics fields, in which electrically conductive composite parts based on polymer material(s) or composite material(s) comprising at least one polymer material and a reinforcing agent (e.g. glass fibers, carbon fibers) and/or conductive particles (e.g. carbon nanotubes, carbon fibers), are used as a replacement for solid metal parts.

Specifically, due to their low weight, their low cost and their adjustable mechanical properties (adjustable in particular in terms of flexibility), these composite parts are increasingly used for fabricating, for example, components in the electronics field (housings, electrical contact supports, connectors, printed circuits, etc.). However, before being used, all these composite parts are generally subjected to a metallization step that consists in forming a metal layer on the surface of the polymer material or of the composite material in order to make said composite parts electrically conductive at the surface. In addition, when these parts are based on polymer material(s) or composite material(s) comprising at least one polymer material and a reinforcing agent such as glass fibers, carbon fibers or aramid fibers, the metallization step may make it possible to give them a mechanical (impact, wear, scratch, etc.) resistance and a resistance to corrosion, to heat, to ultraviolet radiation, to chemical agents (acids, bases, solvents) and to corrosive agents (oils, cleaning products, etc.). By way of example, certain applications such as electronic satellites are subjected to high mechanical and thermal stresses and therefore require the design of electrically conductive high-performance parts in which the metal layer has excellent adhesion to said part.

Furthermore, in certain applications (e.g. electronics field), the metallization is essential for ensuring protection against electromagnetic radiation (electromagnetic shielding) and/or against electrostatic discharges. In other types of applications (e.g. electronic communications field), the metallization should make it possible to attain a level of electrical conductivity that is sufficient, that is to say an electrical conductivity of at least 10⁴ S/m approximately (which corresponds to a surface resistivity of less than 1 ohm/square approximately), and that is similar to that of the solid metal which is approximately 10⁷ S/m. The metallization thus makes it possible to reduce the skin thickness relative to that observed in a conventional composite material comprising one or more polymer materials and metallic conductive particles.

Finally, when these composite parts are based on composite material(s) comprising at least one polymer material and conductive particles, the presence of said conductive particles does not make it possible to attain sufficient levels of electrical conductivity without degradation of the mechanical properties of said composite material. Indeed, the best conductivities are of the order of 10⁻¹ S·m⁻¹ for a lightly filled composite material (i.e. comprising 1% by volume approximately of conductive particles such as carbon nanotubes), and for fill contents of greater than 25% by volume approximately, the mechanical properties of the composite material are degraded. Yet certain electronic applications such as electromagnetic shielding or the production of microwave frequency waveguides require an electrical conductivity level equivalent to that of the metal which polymer materials filled with conductive particles cannot achieve. Therefore, only a continuous surface metallization layer is capable of guaranteeing the required electrical conductivity levels.

The polymer materials used for producing high-performance composite parts are generally selected from polyepoxides and thermoplastic polymers that are thermostable (i.e. that are stable at a temperature greater than or equal to 100° C.) such as polyaryletherketones (PAEK) of polyetheretherketone (PEEK) or polyetherketoneketone (PEKK) type, polyphenylene sulfides (PPS), polyetherimides (PEI), polyethersulfones (PES), polysulfones (PS) or polyimides (PI). These polymer materials are known for having surface properties (e.g. low surface tension, slight roughness, high chemical inertness) that make the assembly operations, and in particular their metallization, difficult. Consequently, various solutions have been proposed in order to ensure an intimate and durable contact between the metal layer and the polymer material, the physicochemical and mechanical characteristics of which are very different.

A first solution consists in depositing a metal at the surface of a part by vacuum metallization. The part is positioned in a chamber in which a vacuum of less than 0.0001 mbar is created. The metal to be deposited is vaporized by heating. This metal vapor obtained is condensed at the surface of the part. This technique is commonly referred to as chemical vapor deposition (CVD). This type of technique is for example described in Audisio [“Dépôts chimiques à partir d'une phase gazeuse” (Chemical depositions from a gas phase), Techniques de l'Ingénieur, Traité de Matériaux, M1 (660), 1, 1985]. However, this technique requires sophisticated and expensive apparatus and the quality of the bond obtained between the polymer material of the part and the metal is unpredictable. In order to promote the intimate and durable contact between the metal layer and the polymer material, large thicknesses of metal are necessary, which increases the weight of the part and its production cost. Finally, the whole of the part should be maintained under vacuum during the metallization, leading to a limitation of the size and of the shape of the parts that can be metallized.

A second solution commonly referred to as physical vapor deposition (PVD) consists for example in carrying out a sputtering of a metal in a reactor placed in which is a part that it is desired to metallize. The application of a potential difference between the target (cathode) and the walls of the reactor within a rarefied atmosphere enables the creation of a cold plasma. Under the effect of the electric field, the positive species of the plasma are attracted by the target and collide with the latter. They then transfer their momentum, thus giving rise to the sputtering of the metal atoms from the target in the form of neutral particles that condense on the part to be metallized. This type of technique is for example described in Billard et al. [“Pulvérisation cathodique magnétron” (Magnetron sputtering), Techniques de l'Ingénieur, Traité de Matériaux, M1 (654), 1, 2005]. Just like CVD, this technique requires sophisticated and expensive apparatus and the quality of the bond between the polymer material of the part and the metal is unpredictable. It cannot be adapted to any type of part either.

A third known solution consists in “activating” a part that it is desired to metallize in order to then carry out, via an aqueous route, a chemical deposition of a conductive metal on this part (i.e. redox reaction) in the presence of a catalyst. The activation of the part may be carried out by a chemical, mechanical or thermal etching for the purpose of creating microcavities (i.e. roughness) at the surface. This etching may be carried out for example by sulfochromic acid, by sandblasting or by flame treatment of the part. The microcavities will then act as anchoring sites for the catalyst which is then applied to the part. By way of example, palladium particles in the presence of tin chloride may activate the surface of the part. The palladium then acts as catalyst. The following step, commonly referred to as an “electroless” step, consists in immersing the part thus “activated” in a chemical deposition bath so as to cover it with a very thin film of conductive metal, for example copper. The surface-conductive part thus obtained can then be metallized by electrodeposition with any metal. However, this technique has several drawbacks. On the one hand, the adhesion of the metal layer is weak, since it is of mechanical origin only due to the anchoring of the deposit in the roughness created by the etching. Therefore, there is no strong bond between the metal and the part, and the bond obtained is not sufficient for the aforementioned applications. On the other hand, this technique requires the use of toxic acids (e.g. sulfochromic acid), a large number of etching, deposition and rinsing baths, and the use of metal catalysts such as palladium, which are relatively expensive. Finally, the application of this technique is limited to the polymer materials capable of undergoing a controlled and uniform etching, such as for example acrylonitrile-butadiene-styrene copolymers, commonly referred to as ABS (dispersions of butadiene nodules in a styrene-acrylonitrile copolymer matrix). This is because other more resistant polymers such as polyaryletherketones (PAEK) (e.g. polyetheretherketone (PEEK) or polyetherketoneketone (PEKK)), polyphenylene sulfides (PPS), polyetherimides (PEI), polyethersulfones (PES), polysulfones (PS) or polyimides (PI) are more stable and, therefore, do not have a sufficient surface roughness for carrying out a deposition after a chemical etching.

In summary, all of these existing techniques offer metal deposits of low cohesion since there are no or few strong chemical interactions between the part and the metal layer. In addition, it is very often necessary to resort to post-treatments of annealing type in order to promote the mechanical strength of the metal layer. These annealings are however often incompatible with the thermal resistance of the polymer materials contained in said part.

Thus, the objective of the present invention is to overcome the drawbacks of the aforementioned prior art and provide a process for metallizing an electrically insulating solid substrate comprising at least one polymer material in order to obtain a high-performance composite part that is electrically conductive at the surface, said process being economical, easy to implement, more environmentally friendly, able to be used with any type of polymer material contained in said substrate, and able to produce metal deposits that have both a sufficient thickness and a sufficient adhesion.

In addition, another objective of the present invention is to develop a high-performance composite part that is electrically conductive at the surface in which the polymer material/metal bond is strong enough so that it can be used in the aforementioned cutting-edge applications.

These objectives are achieved by the invention which will be described below.

A first subject of the invention is therefore a process for preparing a high-performance composite part that is electrically conductive at the surface (CP₁) comprising an electrically insulating solid substrate (S), a conductive film (CF) deposited on at least one portion of the surface of the substrate (S), and a metal layer (ML) deposited on at least one portion of the free surface of the conductive film (CF),
the electrically insulating solid substrate (S) comprising at least one polymer material (P₁), and
the metal layer (ML) comprising at least one metal (M₁),

said process being characterized in that it comprises at least the following steps:

1) a step of preparing a liquid composition comprising at least one polymer material (P₂) and at least one metal (M₂) in the form of filiform nanoparticles, said liquid composition comprising from 0.2% to 10% by volume approximately of said metal (M₂) relative to the total volume of the liquid composition,

2) a step of applying the liquid composition from step 1) to at least one portion of the surface of said electrically insulating substrate (S),

3) a step of drying, and optionally of heat treatment, of the liquid composition in order to obtain an intermediate composite part (CP₂) comprising the electrically insulating solid substrate (S) and the conductive film (CF) deposited on at least one portion of the surface of the substrate (S), said conductive film (CF) comprising said polymer material (P₂) and from 1% to 10% by volume approximately of said metal (M₂) in the form of filiform nanoparticles relative to the total volume of the conductive film (CF),

4) a step of electrodeposition (i.e. electroplating or electrochemical deposition) of at least one metal (M₁) on at least one portion of the free surface of the conductive film (CF), in order to obtain said composite part (CP₁).

In the invention, the expression “free surface of the conductive film (CF)” means the surface which is not in direct contact with said electrically insulating solid substrate (S) and which is therefore free to be metallized according to step 4) of the process according to the invention.

In the invention, the expression “electrically insulating solid substrate (S)” means a solid substrate having a surface resistivity of strictly greater than 100 ohms/square.

In the invention, the expression “high-performance composite part that is electrically conductive at the surface” means a high-performance composite part having an electrical conductivity of greater than or equal to 10⁴ S/m approximately (which corresponds to a surface resistivity of less than 1 ohm/square approximately), and preferably greater than or equal to 10⁵ S/m approximately.

Thus, the process of the invention makes it possible to obtain a composite part (CP₁) comprising the superposition of at least the following three materials: an electrically insulating substrate (S), a conductive film (CF) and a metal layer (ML). The conductive film (CF) then acts as a conductive primer layer. Steps 2) and 3) that make it possible to form this conductive primer layer are essential in order to then be able to carry out the electrodeposition according to step 4). Specifically, the presence of conductive filiform nanoparticles in the conductive film (CF) makes it possible to promote, during the electrodeposition step 4), the homogenous distribution of the metal (M₁) at the surface of said conductive film (CF), and thus to obtain the formation of a homogenous and even metal layer (ML).

Furthermore, the filiform nanoparticles do not need to be used in large volume amounts in the conductive film (CF) (i.e. in amounts greater than 10% by volume), thus leading to a reduction in the production cost of the composite part (CP₁), better mechanical properties of said conductive film (CF), and consequently of the behavior of the metal layer (ML).

In addition, the process of the invention uses a small number of steps and implements simple steps that can be easily transposed to the industrial environment. It makes it possible to produce parts of complex shapes both of large and very small dimensions, with no particular precautions (e.g. deposition under ambient atmosphere), having a strong bond between the metal layer (ML) and the substrate (S) via the conductive film (CF). Furthermore, the process makes it possible to retain the deformability of the conductive film (CF) and of the metal layer (ML) during a thermal shock, and thus to avoid the blistering that may for example be observed when the metallization takes place via CVD.

The substrate (S) may additionally comprise a reinforcing agent and/or conductive particles.

The reinforcing agent may be selected from carbon fibers, glass fibers, aramid (e.g. Kevlar®) fibers and mixtures thereof.

The conductive particles may be selected from carbon nanotubes, graphene, carbon black and mixtures thereof.

The conductive particles may be metal particles.

According to one preferred embodiment of the invention, the substrate (S) comprises at most 10% by volume of conductive particles and/or reinforcing agent in order to avoid the degradation of its mechanical properties.

The shape and the size of the substrate (S) may be selected according to the uses intended for the composite part CP₁.

Any shape and any size may be suitable.

However, large sizes of substrate (S) are preferred (e.g. greater than 100 cm²) for the production of high-performance composite parts that are electrically conductive at the surface for the electronics, railroad, aeronautical, aerospace and motor vehicle industries.

The nature of the polymer material (P₁) is not critical, it may be selected from any type of thermoplastic polymer and any type of thermosetting polymer.

As examples of thermoplastic polymers (P₁), mention may be made of high-performance polymers such as polyaryletherketones (PAEK) [e.g. polyetheretherketones (PEEK), polyetherketoneketones (PEKK), polyetherketones (PEK), polyetheretherketoneketones (PEEKK), polyether-ketoneetherketoneketones (PEKEKK)], polyphenylene sulfides (PPS), polyetherimides (PEI), polyethersulfones (PES), polysulfones (PS) or polyimides (PI); engineering polymers such as polyamides (PA), polyamide-imides (PAI), polycarbonates (PC), polyvinylidene fluorides (PVdF), copolymers of polyvinylidene fluoride and trifluoroethylene [P(VdF-TrFE)] or of hexafluoropropene [P(VdF-HFP)]; or mixtures thereof.

As examples of thermosetting polymers (P₁), mention may be made of polyepoxides, polyurethanes (PU), or mixtures thereof. Polyepoxides are preferred.

The polymer material (P₂) may be selected from thermoplastic polymers and thermosetting polymers.

(P₂) is preferably a thermosetting polymer.

As examples of thermoplastic polymers (P₂), mention may be made of high-performance polymers such as polyaryletherketones (PAEK) [e.g. polyetheretherketones (PEEK), polyetherketoneketones (PEKK), polyetherketones (PEK), polyetheretherketoneketones (PEEKK), polyether-ketoneetherketoneketones (PEKEKK)], polyphenylene sulfides (PPS), polyetherimides (PEI), polyethersulfones (PES), polysulfones (PS) or polyimides (PI); engineering polymers such as polyamides (PA), polyamide-imides (PAI), polycarbonates (PC), polyvinylidene fluorides (PVdF), copolymers of polyvinylidene fluoride and trifluoroethylene [P(VdF-TrFE)] or of hexafluoropropene [P(VdF-HFP)]; or mixtures thereof.

As examples of thermosetting polymers (P₂), mention may be made of polyepoxides, polyurethanes (PU), or mixtures thereof. Polyurethanes are preferred.

The metal (M₂) may be a stainless metal, that is to say which does not react with the oxygen from the air to form a “passivation” layer.

According to one preferred embodiment, (M₂) is selected from silver, gold, platinum and mixtures thereof.

In the present invention, the expression “filiform nanoparticles” means particles having:
a length (L₁), extending in a main direction of elongation,
two dimensions (D₁) and (D₂), referred to as orthogonal dimensions, extending along two transverse directions that are orthogonal to one another and orthogonal to said main direction of elongation, said orthogonal dimensions (D₁, D₂) being smaller than said length (L₁) and less than 500 nm, and,
two ratios (F₁) et (F₂), referred to as shape factors, between said length (L₁) and each of the two orthogonal dimensions (D₁) and (D₂), said shape factors (F₁, F₂) being greater than 50.

The expression “shape factor” means the ratio between the length (L₁) of a filiform nanoparticle, and one of the two orthogonal dimensions (D₁, D₂) of said filiform nanoparticle.

According to one preferred embodiment, the two orthogonal dimensions (D₁, D₂) of a filiform nanoparticle are the diameter (D) of its transverse cross section. It is then referred to as a “nanorod” or “nanowire”.

A filiform nanoparticle may also be a “ribbon” in which the two orthogonal directions of the filiform nanoparticle according to the invention are its width (L₂) (first orthogonal dimension) and its thickness (E) (second orthogonal dimension).

More particularly, the filiform nanoparticles according to the invention are advantageously characterized by at least one of the following features:
the two orthogonal dimensions (D₁, D₂) of the filiform nanoparticles are between 50 nm and 250 nm approximately, and preferably between 100 nm and 200 nm;
the length (L₁) is between 1 μm and 150 μm approximately, and preferably between 25 μm and 70 μm approximately;
the shape factors (F₁, F₂) are between 100 and 200 approximately, and preferably of the order of 150 approximately.

According to one preferred embodiment, the liquid composition from step 1) comprises no pigment and/or dye. Indeed, the pigments (e.g. inorganic fillers) and/or dyes generally used may impair the mechanical properties of the conductive film (CF).

According to one particular embodiment, the liquid composition from step 1) comprises no carbon-based fillers such as carbon black, carbon nanotubes, carbon fibers, carbon nanofibers, graphite, graphene, or mixtures thereof. Indeed, their presence may impair the homogeneity of the deposit of the conductive film (CF) and its mechanical properties.

According to one particular embodiment, the liquid composition from step 1) may additionally comprise a metal (M₃) identical to the metal (M₂) but not being in the form of filiform nanoparticles. The metal (M₃) may be, for example, in form of nanoscale and/or microscale spherical particles, powder or flakes.

According to one particular and preferred embodiment of the invention, step 1) comprises the following sub-steps:

1ₐ) a step of preparing a dispersion of at least one metal (M₂) in the form of filiform nanoparticles in a solvent,

1_{b}) a step of mixing the dispersion from the preceding step 1ₐ) with at least one polymer material (P₂),

1_{c}) a step of homogenizing the mixture from the preceding step 1_{b}) in order to form a liquid composition comprising at least one polymer material (P₂) and at least one metal (M₂) in the form of filiform nanoparticles, said liquid composition comprising from 0.2% to 10% by volume approximately of said metal (M₂) relative to the total volume of the liquid composition.

The solvent from step 1ₐ) may be selected from hydrocarbon solvents such as alkanes, alkenes, toluene or xylene, oxygenated solvents such as alcohols, ketones, acids, esters, DMF or DMSO, chlorinated solvents, water and mixtures thereof.

The solvent from step 1ₐ) is preferably a solvent that can easily be evaporated, in order to facilitate the formation of the conductive film (CF) during step 3).

When the polymer material (P₂) is a thermoplastic polymer, it is generally used “as is” in the process of the invention, that is to say that said process does not comprise a step of crosslinking said polymer material (P₂), the latter already being in polymer form.

In order to facilitate the shaping of said thermoplastic polymer material (P₂) during step 3), the solvent from step 1ₐ) is selected so that said thermoplastic polymer material (P₂) is soluble therein.

When the polymer material (P₂) is a thermosetting polymer, the mixture from step 1_{b}) additionally comprises a hardener (i.e. a crosslinking agent).

By way of example, mention may be made of an isocyanate-type hardener when (P₂) is a polyurethane.

In one particular embodiment, the thermosetting polymer material (P₂) is dispersed beforehand in a solvent prior to step 1_{b}), said solvent preferably being identical to that used during step 1ₐ). This embodiment is particularly advantageous when the thermosetting polymer material (P₂) is in solid form, in particular in powder form or else in the form of a material having a very high viscosity.

Step 1_{c}) may be carried out by ultrasonic waves, in particular at a frequency ranging from 20 kHz to 170 kHz approximately, and at a power that may range from 5 W to 50 W approximately per 5 second pulse.

When the polymer material (P₂) is a liquid thermosetting polymer, step 1) may additionally comprise, after the homogenization step 1_{c}), a step 1_{d}) of evaporating the solvent of the liquid composition from step 1_{c}).

This step of evaporating the solvent of the liquid solution may be carried out by heat treatment, in air or under vacuum.

In one preferred embodiment, step 2) is carried out by spraying the liquid composition from step 1) onto at least one portion of the surface of said electrically insulating solid substrate (S), or with the aid of a brush, or else by immersing at least one portion of the surface of said electrically insulating solid substrate (S) in the liquid composition from step 1).

When step 2) is performed by spraying, this may be carried out with the aid of a compressed air spray gun.

Step 2) may be carried out at a temperature sufficient to enable the liquid composition from step 1) to be kept in the liquid state.

Preferably, step 2) is carried out over the whole surface of said electrically insulating solid substrate (S).

The process of the invention may additionally comprise a step i), prior to step 2), of degreasing the substrate (S).

This step i) makes it possible to eliminate the packaging dust, handling marks and other residues. It makes it possible to improve the wettability of the substrate (S) during step 2) of applying the liquid composition. Indeed, the liquid composition may have a high viscosity and tend to form air bubbles at the surface of the substrate (S). The good wettability of the substrate (S) therefore makes it possible to avoid this phenomenon and consequently to improve the homogeneity and the fineness of the deposit of the conductive film (CF) during step 2).

Step i) may be carried out by immersing the substrate (S) in a degreasing bath. The degreasing bath may be slightly alkaline (e.g. presence of sodium hydroxide) and may comprise surfactants.

In one preferred embodiment, the immersion step i) is carried out for 2 to 5 min approximately, at a temperature that may range from 25° C. to 50° C. approximately.

Step 3) makes it possible to form a conductive film (CF) on at least one portion of the surface of said electrically insulating solid substrate (S).

In one particular embodiment, the conductive film (CF) from step 3) comprises from 1% to 5% by volume approximately of metal (M₂), and preferably from 4% to 5% by volume approximately of metal (M₂) relative to the total volume of said conductive film (CF). The use of these small amounts of metal (M₂) makes it possible to result in a lightly filled conductive film (CF), and not to make the composite part (CP₁) heavy, while retaining the mechanical properties of the conductive film (CF). A structural mechanical support for the electrolytic metal deposition of step 4) and a very good adhesion to the substrate (S) are then guaranteed. By way of example, a conductive film made of polyurethane having a thickness of 10 μm leads to an excess weight of only 14.6 g/m².

It should be noted that the use of an amount of metal (M₂) of greater than 10% by volume in the conductive film (CF) may lead to a degradation of these mechanical properties.

The inventors of the present application have surprisingly discovered that for equivalent volume amounts (i.e. from 1% to 5% by volume approximately), replacing the filiform nanoparticles with particles in the form of spherical particles, flakes, or powder did not make it possible to obtain a sufficiently conductive film. Indeed, at least 15% to 20% by volume of these particles in the form of spherical particles, flakes, or powder are needed in order to be able to obtain such a sufficient conductivity. However, with such volume proportions, a degradation of the mechanical properties, and consequently of the behavior of the metal layer (ML), is observed. The filiform nanoparticles of the invention have two essential characteristics for the production of lightly filled conductive films (CF). Their shape factor is high (between 50-200), which makes it possible to envisage obtaining percolation thresholds for small amounts of conductive filler. Furthermore, since these filiform nanoparticles are metallic, they have the intrinsic conductivity of the metal that forms them.

The thickness of the conductive film (CF) may range from 10 μm to 150 μm approximately, and preferably from 15 μm to 35 μm approximately.

Below 10 μm, a uniform conductivity of the conductive film (CF) deposited on the substrate (S) is not guaranteed, and above 150 μm the production cost of the composite part (CP₁) becomes high.

When the liquid composition additionally comprises a metal (M₃), the conductive film obtained in step 3) may comprise from 0.5% to 10% approximately by volume of metal (M₃) relative to the total volume of the conductive film (CF).

Step 3) makes it possible to make all or some of the surface of the substrate (S) sufficiently conductive to then be able to carry out the electrodeposition step 4).

In the invention, the expression “conductive film (CF)” means a film having a surface resistivity of strictly less than 1000 ohms/square, and preferably of strictly less than 100 ohms/square in order to enable the electrodeposition step 4) to be carried out.

The drying time and temperature used during step 3) are adapted to the nature of the liquid composition of step 1) (i.e. types of polymer material (P₂), solvent, etc.).

Step 3) also makes it possible, in certain cases, to carry out and/or terminate the polymerization of the polymer material (P₂).

When the polymer material (P₂) is a thermoplastic polymer, it is already in polymer form in the liquid composition of step 1). Thus, step 3) only comprises the drying of the liquid composition, in particular in air. The drying makes it possible to evaporate the solvent from step 1ₐ) and thus to form the conductive film (CF).

When the polymer material (P₂) is a thermosetting polymer, it is not yet in polymer form in the liquid composition of step 1). Thus, step 3) comprises the drying of the liquid composition, in particular in air, and optionally the heat treatment of said liquid composition. The drying makes it possible to evaporate the solvent from step 1ₐ), and optionally the solvent in which the thermosetting polymer material P₂ has been dispersed beforehand prior to step 1_{b}), to initiate the polymerization, and thus to form the conductive film (CF).

The heat treatment of the liquid composition makes it possible to initiate and/or accelerate the polymerization.

It may be carried out in an oven, at a temperature that may range from 25° C. to 180° C.

The process of the invention may additionally comprise, between steps 3) and 4), a step ii) of sanding at least one portion of the free surface of the conductive film (CF) in order to adapt the surface finish before step 4).

The electrodeposition step 4) is generally carried out in an electrochemical cell connected to a controlled voltage and/or current source, and comprising at least:
a cathode formed by the intermediate composite part CP₂ obtained in step 3), and connected to the negative terminal of the voltage and/or current source,
an anode connected to the positive terminal of the voltage and/or current source, and
a liquid electrolyte comprising at least one solution of a precursor compound of the metal (M₁) and optionally an ionically conductive salt.

The solution of precursor compound of the metal M₁ comprises cations of the metal M₁ in solution that are reduced during the application of a controlled voltage and/or current source, and then form a continuous metal layer (ML) on at least one portion of the free surface of the conductive film (CF). The free surface of the conductive film (CF) is preferably on the opposite side to the anode.

Preferably, step 4) is carried out over the entire free surface of said conductive film (CF).

The electrodeposition may be carried out at constant, pulsed, alternating or oscillating current, or under a constant, pulsed, alternating or oscillating voltage, or under a constant, pulsed, alternating or oscillating power.

The metal (M₁) is preferably selected from Cu, Sn, Co, Fe, Pb, Ni, Cr, Au, Pd, Pt, Ag, Bi, Sb, Al, Li and mixtures thereof. Among these metals, Ag and Au are particularly preferred.

When (M₁) is Al or Li, the precursor compound of the metal (M₁) is used in solution in an organic solvent.

When (M₁) is Cu, Sn, Co, Fe, Pb, Ni, Cr, Au, Pd, Pt, Sb, Ag or Bi, the precursor compound of the metal (M₁) may be used in aqueous solution or in solution in an organic solvent.

The precursor of the metal (M₁) is preferably selected from sulfates, sulfamates, borates, halides (more particularly chlorides and fluorides), complexes based on cyanides or on amines, and hydrides.

The organic solvent is preferably selected from alkylene or dialkyl carbonates, such as for example propylene carbonate (PC), ethylene carbonate (EC) and diethyl carbonate (DEC).

The ionically conductive salt of the liquid electrolyte is preferably selected from conductive salts that are electrochemically stable under the electrodeposition conditions. It may be a salt of the metal (M₁) to be deposited. The addition of an ionically conductive salt is not essential. However, for low concentrations of precursor compound of the metal (M₁), the conductivity of the electrolyte is low, or even insufficient, and in this case it is useful to add an ionically conductive salt to the electrolyte.

In the electrochemical cell used for the implementation of step 3), the anode may be of the soluble anode type, formed by a metal identical to the metal (M₁), which makes it possible to maintain a constant concentration of metal (M₁) ions in the solution and to limit the voltage at the terminals of the cell. The anode may also be formed by a metal that is uncorrodable in the solution and at which the oxidation of the solvent will then take place. The anode may in addition be of the soluble anode type formed by a metal other than the metal (M₁) to be deposited, but in this case the electrodeposition conditions must be adjusted so as to prevent the deposition, on the conductive film (CF), of an alloy of the metal (M₁) and of the metal forming the anode.

According to one preferred embodiment, the composite part (CP₁) obtained by the process of the invention comprises no other layer(s) than the metal layer (ML), the conductive film (CF) and the substrate (S).

In one particular embodiment, the thickness of the metal layer (ML) may range from 1 μm to 500 μm approximately, and preferably from 5 μm to 50 μm approximately.

Thus, the process of the invention makes it possible to metallize parts made of optionally reinforced polymer materials that initially have an insufficient electrical conductivity.

In one particular embodiment, the electrochemical cell additionally comprises a sponge (i.e. a pad) into which the liquid electrolyte is incorporated.

Thus, the sponge is soaked with said liquid electrolyte and it is placed between the anode and the cathode.

This embodiment is particularly advantageous when the intermediate composite part CP₂ obtained in step 3) is too large to be immersed in the liquid electrolyte or when it is desired to electrodeposit the metal (M₁) on only certain portions of its surface.

A second subject of the invention is a high-performance composite part that is electrically conductive at the surface (CP₁) comprising an electrically insulating solid substrate (S), a conductive film (CF) deposited on at least one portion of the surface of the electrically insulating substrate (S), and a metal layer (ML) deposited on at least one portion of the free surface of the conductive film (CF), said part (CP₁) being characterized in that:
the electrically insulating solid substrate (S) comprises at least one polymer material (P₁), and
the conductive film (CF) comprises at least one polymer material (P₂) and at least one metal M₂ in the form of filiform nanoparticles, said conductive film (CF) comprising from 1% to 10% by volume approximately of said metal (M₂), preferably from 1% to 5% by volume approximately of the metal (M₂), and more preferably from 4% to 5% by volume approximately of the metal (M₂), relative to the total volume of the conductive film,
the metal layer (ML) comprises at least one metal (M₁).

The substrate (S), the conductive film (CF), the metal layer (ML), the metal (M₁), the metal (M₂), the polymer material (P₁) and the polymer material (P₂) are as defined in the first subject of the invention.

According to one preferred embodiment, the conductive film (CF) comprises no pigment and/or dye. Indeed, the pigments and/or dyes generally used may impair its mechanical properties.

According to one particular embodiment, the conductive film (CF) comprises no carbon-based fillers such as carbon black, carbon nanotubes, carbon fibers, carbon nanofibers, graphite, graphene, and mixtures thereof. Indeed, their presence may impair the homogeneity of the deposit of the conductive film (CF) and its mechanical properties.

A third subject of the invention is the use of a high-performance composite part that is electrically conductive at the surface (CP₁) as prepared according to the process defined in the first subject of the invention or as defined in the second subject of the invention in housings for electrical and electronic components.

A fourth subject of the invention is the use of the process for preparing a high-performance composite part that is electrically conductive at the surface (CP₁) as defined in the first subject of the invention for improving the abrasion resistance, wear resistance and resistance to harsh atmospheric and/or chemical conditions of an electrically insulating part.

A fifth subject of the invention is the use of the process for preparing a high-performance composite part that is electrically conductive at the surface (CP₁) as defined in the first subject of the invention for ensuring the protection of an electrically insulating part against electromagnetic radiation (electromagnetic shielding) and/or against electrostatic discharges.

A sixth subject of the invention is the use of the process for preparing a high-performance composite part that is electrically conductive at the surface (CP₁) as defined in the first subject of the invention for improving the surface electrical conductivity of a material.

The present invention is illustrated by the examples below, to which it is not however limited.

### EXAMPLES

The raw materials used in the examples are listed below:
10 cm×10 cm substrate produced by stacking sheets of a composite material based on polyetheretherketone (PEEK) reinforced with carbon fibers (in a proportion of 65% by volume of carbon fibers relative to the total volume of the material), said sheets being sold under the trade name APC-2 by Cytec Industries, (hereinafter referred to as Substrate S1);
10 cm×10 cm substrate produced by stacking sheets of a composite material based on polyepoxide resin reinforced with carbon fibers (T700, Toray), in a proportion of 66% by volume of carbon fibers relative to the total volume of the material, said sheets being sold under the trade name HexPly® M21 by the company Hexcel (hereinafter referred to as Substrate S2);
10 cm×10 cm substrate produced from a composite material comprising a matrix made of polyphenylene sulfide (PPS) reinforced with carbon fibers in a proportion of 45% by volume, said material being sold under the trade name Cetex® TC1100 by the company TenCate (hereinafter referred to as Substrate S3);
10 cm×10 cm substrate made of polyetheretherketone (PEEK) sold under the trade name Victrex 450G (hereinafter referred to as Substrate S4);
aqueous dispersion of a hydroxy-functional acrylic resin made of polyurethane (PU) sold under the trade name Macrynal® VSM 6299W/42WA by the company Allnex,
liquid polyepoxide resin comprising an amine-type crosslinking agent, sold under the trade name HexFlow® RTM 6 by the company Hexcel,
nickel, Good Fellow,
ethanol, Sigma Aldrich,
silver particles in the form of flakes having a size<20 μm, 90% purity, Alfa Aesar,
multiwall carbon nanotubes sold under the trade name Graphistrength® by the company Arkema,
aliphatic polyisocyanate (crosslinking agent), sold under the trade name Easaqua® X D401 by the company Vencorex.

Unless otherwise indicated, all these raw materials were used as received from the manufacturers.

### Example 1

### Preparation of a Composite Part CP_{1-A} in Accordance with the Invention and Prepared According to the Process in Accordance with the Invention

A dispersion comprising 3.21 g of silver nanowires and 100 ml of ethanol was prepared. The silver nanowires were prepared beforehand according to a growth process in solution from silver nitrate (AgNO₃) and polyvinylpyrrolidone (PVP) as described by Sun Y. G. et al., “Crystalline silver nanowires by soft solution processing”, Nano Letters, 2002. 2(2): p. 165-168, with a PVP/AgNO₃ ratio of 1.53.

The dispersion of silver nanowires was mixed with 9.29 g of an aqueous dispersion of Macrynal® VSM 6299W/42WA acrylic resin and 1.61 g of Easaqua® X D401 polyisocyanate so as to obtain a mixture which was then homogenized in an ultrasonic bath, at a frequency of 50 kHz and a power of 25 W per 5 second pulse. A liquid composition comprising ethanol, the PU acrylic resin, the polyisocyanate and the silver nanowires was thus obtained.

The liquid composition was then deposited on a portion of the surface (one of the faces) of the substrate S1 by spraying with the aid of a compressed air spray gun.

After drying in air then heat treatment at 80° C. for 30 minutes in an oven, a conductive film (CF) with a thickness of 30 μm, deposited on a portion of the surface of the substrate S1, was obtained, said conductive film (CF) comprising 4.5% by volume of silver nanowires relative to the total volume of the conductive film (CF). At the end of this step, an intermediate composite part CP_{2-A} was thus obtained.

Next, nickel was deposited on the conductive film (CF) (i.e. on the free surface of the conductive film) by electrodeposition with the aid of an electrochemical cell comprising:
an anode formed of a nickel plate (Goodfellow, 99.99%), and electrically connected to a current source,
the conductive film, as cathode, placed parallel to the anode at a distance of 2 cm approximately and electrically connected to said current source, and
a Watts solution comprising nickel sulfate at a concentration of 330 g/l, nickel chloride at a concentration of 45 g/l, and boric acid at a concentration of 37 g/l.

The deposition was carried out at 25° C., with a voltage set at 3 V approximately and an intensity of 15 mA approximately for 15 minutes approximately. A nickel layer (ML) of approximately 2 μm deposited on the conductive film (CF) was thus obtained.

A composite part CP_{1-A} was thus obtained comprising a first material formed by the substrate S1, a second material formed by the conductive film (CF) comprising a PU resin and silver nanowires, and finally a third material formed by a nickel layer (ML).

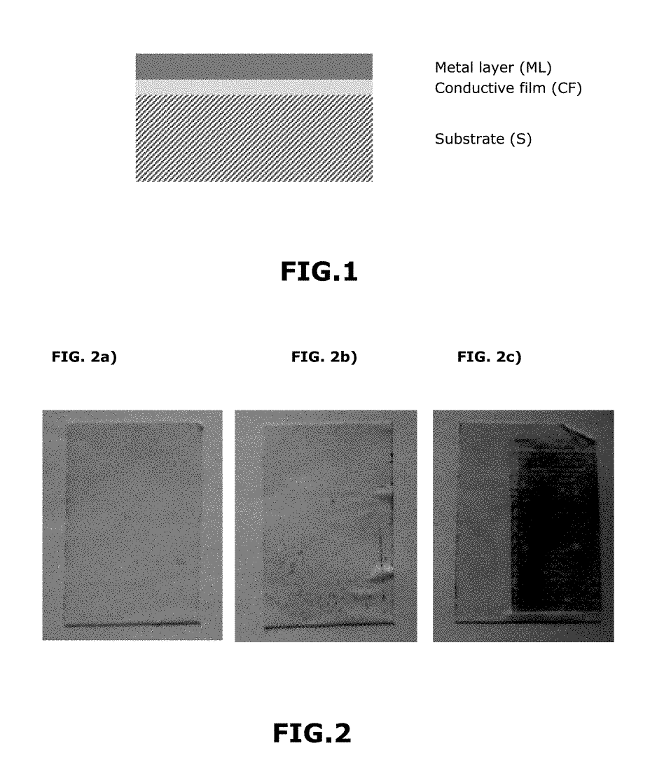

FIG. 1 is a schematic representation of the composite part (CP_{1-A}) of the invention.

### Example 2

### Preparation of a Composite Part CP_{1-B} in Accordance with the Invention and Prepared According to the Process in Accordance with the Invention

A dispersion comprising 4.34 g of silver nanowires and 100 ml of acetone was prepared.

The dispersion was mixed with 10 g of HexFlow® RTM 6 liquid polyepoxide resin so as to obtain a mixture which was then homogenized in an ultrasonic bath under the conditions as described in example 1. The acetone was evaporated at 80° C. for 10 minutes using a Buchi rotary evaporator of vertical R3 type.

The mixture obtained was heated at 80° C. so as to obtain a liquid composition comprising the polyepoxide resin and the silver nanowires. This mixture may remain fluid at 80° C. for 10 hours before the solidification thereof.

The liquid composition was then deposited on at least one portion of the surface (one of the faces) of the substrate S2, by spraying with the aid of the compressed air spray gun from example 1. This spray gun was able to keep the HexFlow® RTM 6 polyepoxide resin at a temperature of 80° C. in order to prevent it from solidifying.

After drying in air then heat treatment in an oven at 180° C. for 1 hour, a conductive film (CF) with a thickness of 30 μm, deposited on at least one portion of the surface of the substrate S2, was obtained, said conductive film comprising 4.5% by volume of silver nanowires relative to the total volume of the conductive film. At the end of this step, an intermediate composite part CP_{2-B} was thus obtained.

Next, nickel was deposited under the same electrodeposition conditions as those described in example 1.

A nickel layer (ML) of approximately 2 μm deposited on the conductive film (CF) was thus obtained.

A composite part CP_{1-B} was thus obtained comprising a first material formed by the composite substrate made of polyepoxide composite resin (S2), a second material formed by the conductive film (CF) comprising a polyepoxide resin and silver nanowires, and finally a third material formed by a nickel layer (ML).

### Example 3

### Preparation of a Composite Part CP_{1-C} in Accordance with the Invention and Prepared According to the Process in Accordance with the Invention

A dispersion comprising 3.21 g of silver nanowires and 100 ml of ethanol was prepared.

The dispersion of silver nanowires was mixed with 9.29 g of Macrynal® VSM 6299W/42WA and 1.61 g of Easaqua® X D401 polyisocyanate so as to obtain a mixture which was then homogenized in an ultrasonic bath under the conditions as described in example 1. A liquid composition comprising ethanol, the PU acrylic resin, the polyisocyanate and the silver nanowires was thus obtained.

The liquid composition was then deposited on at least one portion of the surface of the substrate S2 by spraying with the aid of the compressed air spray gun from example 1.

After drying in air then heat treatment at 80° C. for 30 minutes in an oven, a conductive film (CF) with a thickness of 30 μm, deposited on at least one portion of the surface of the substrate S2, was obtained, said conductive film comprising 4.5% by volume of silver nanowires relative to the total volume of the conductive film. At the end of this step, an intermediate composite part CP_{2-C} was thus obtained.

Next, nickel was deposited under the same electrodeposition conditions as those described in example 1.

A nickel layer (ML) of approximately 2 μm deposited on the conductive film (CF) was thus obtained.

A composite part CP_{1-C} was thus obtained comprising a first material formed by the composite substrate made of polyepoxide resin (S2), a second material formed by the conductive film (CF) comprising a PU resin and silver nanowires, and finally a third material formed by a nickel layer (ML).

### Example 4

### Preparation of a Composite Part CP_{1-D} in Accordance with the Invention and Prepared According to the Process in Accordance with the Invention

A dispersion comprising 3.21 g of silver nanowires and 100 ml of ethanol was prepared.

The dispersion was mixed with 9.29 g of Macrynal® VSM 6299W/42WA and 1.61 g of Easaqua® X D401 polyisocyanate so as to obtain a mixture which was then homogenized in an ultrasonic bath under the conditions as described in example 1. A liquid composition comprising ethanol, the PU acrylic resin, the polyisocyanate and the silver nanowires was thus obtained.

The liquid composition was then deposited on at least one portion of the surface of the substrate S3 by spraying with the aid of the compressed air spray gun from example 1.

After drying in air then heat treatment at 80° C. for 30 minutes in an oven, a conductive film (CF) with a thickness of 30 μm, deposited on at least one portion of the surface of the substrate S3, was obtained, said conductive film (CF) comprising 4.5% by volume of silver nanowires relative to the total volume of the conductive film. At the end of this step, an intermediate composite part CP_{2-D} was thus obtained.

Next, nickel was deposited under the same electrodeposition conditions as those described in example 1.

A nickel layer (ML) of approximately 2 μm deposited on the conductive film (CF) was thus obtained.

A composite part CP_{1-D} was thus obtained comprising a first material formed by the composite substrate made of PPS resin, a second material formed by the conductive film (CF) comprising a PU resin and silver nanowires, and finally a third material formed by a nickel layer (ML).

### Example 5

### Preparation of a Composite Part CP_{1-E} in Accordance with the Invention and Prepared According to the Process in Accordance with the Invention

A dispersion comprising 3.21 g of silver nanowires and 100 ml of ethanol was prepared.

The dispersion was mixed with 9.29 g of Macrynal® VSM 6299W/42WA and 1.61 g of Easaqua® X D401 polyisocyanate so as to obtain a mixture which was then homogenized in an ultrasonic bath under the conditions as described in example 1. A liquid composition comprising ethanol, the PU acrylic resin, the polyisocyanate and the silver nanowires was thus obtained.

The liquid composition was then deposited on at least one portion of the surface of the substrate S4 by spraying with the aid of the compressed air spray gun from example 1.

After drying in air then heat treatment at 80° C. for 30 minutes in an oven, a conductive film (CF) with a thickness of 30 μm, deposited on at least one portion of the surface of the substrate S4, was obtained, said conductive film (CF) comprising 4.5% by volume of silver nanowires relative to the total volume of the conductive film. At the end of this step, an intermediate composite part CP_{2-E} was thus obtained.

Next, nickel was deposited under the same electrodeposition conditions as those described in example 1.

A nickel layer (ML) of approximately 2 μm deposited on the conductive film (CF) was thus obtained.

A composite part CP_{1-E} was thus obtained comprising a first material formed by the substrate made of non-reinforced PEEK resin (S4), a second material formed by the conductive film (CF) comprising a PU resin and silver nanowires, and finally a third material formed by a nickel layer (ML).

### Comparative Example 6

### Comparison of the Intermediate Composite Part CP_{2-C} in Accordance with the Invention with Intermediate Composite Parts CP_{2-A′}, CP_{2-B′} and CP_{2-C′} not in Accordance with the Invention

The intermediate composite part CP_{2-C} in accordance with the invention and as prepared in example 3 above was compared with three intermediate composite parts CP_{2-A′}, CP_{2-B′} and CP_{2-C′} not in accordance with the invention.

The intermediate composite part CP_{2-A′} that is not part of the invention was prepared using the same process as that described in example 3 but in which the silver nanowires were replaced by silver particles in the form of flakes having a size of strictly less than 20 μm.

The intermediate composite part CP_{2-B′} that is not part of the invention was prepared using the same process as that described in example 3 but in which the silver nanowires were replaced by multiwall carbon nanotubes.

The intermediate composite part CP_{2-C′} that is not part of the invention was prepared using the same process as that described in example 3 but in which the silver nanowires were replaced by silver particles in the form of flakes having a size of strictly less than 20 μm and the conductive film (CF) obtained comprised 25% by volume of said silver particles relative to the total volume of the conductive film.

The surface resistivities of the intermediate composite parts CP_{2-C}, CP_{2-A′}, CP_{2-B′} and CP_{2-C′} were measured with the aid of an apparatus sold under the trade name Keithley® 2420 SourceMeter in 4-wire mode and a concentric ring probe according to ASTM Standard D257-99.

Step 4) of electrodeposition in accordance with the invention onto these intermediate composite parts was then carried out when this was technically possible.

Finally, the mechanical resistances of the intermediate composite parts CP_{2-C}, CP_{2-A′}, CP_{2-B′} and CP_{2-C′} were evaluated with the aid of the adhesive tape (A-Tape) test which consists in applying a piece of adhesive tape to a coating and in pulling it off in order to see if the coating has a good adhesion to said coating.

Table 1 below shows the results of the resistivity, electrodeposition test, mechanical resistance via the A-Tape test, and also the references for the corresponding images of each of the intermediate composite parts CP_{2-C}, CP_{2-A′}, CP_{2-B′} and CP_{2-C′} prepared above.

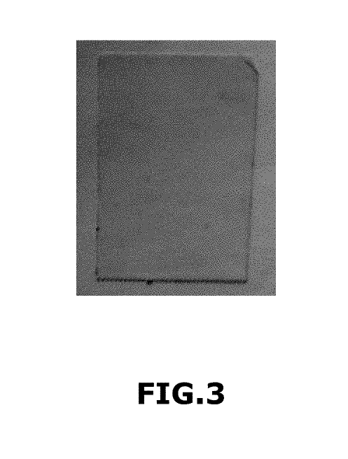

TABLE 1

| | | | | Observation of |
|---|---|---|---|---|
| Composite | | Electro- | | the surface of |
| part | Resistivity | deposition | A-Tape | the composite |
| CP₂ | (Ω/square) | step 4) test | test | part CP₂ |
| CP_{2-C} | ~1 | OK | OK | FIG. 2a |
| CP_{2-A′} (*) | >1000000 | Failure | — | FIG. 2b |
| CP_{2-B′} (*) | ~1000 | Failure | — | FIG. 2c |
| CP_{2-C′} (*) | ~1 | OK | Failure | FIG. 3 |

(*) not in accordance with the invention

Thus, the results from table 1 show that the size, the shape, the content and the nature of the compound introduced into the conductive film are determining factors for enabling, on the one hand, the electrodeposition of the metal M₁ according to step 4) and, on the other hand, a good mechanical resistance of the composite part of the invention.

Owing to the use of filiform nanoparticles at 4.5% by volume, the mechanical properties of the conductive film (CF) are maintained, which is not the case when 25% by volume of particles in the form of flakes are used.

1. A process for preparing a high-performance composite part that is electrically conductive at the surface having an electrically insulating solid substrate, a conductive film deposited on at least one portion of the surface of the substrate, and a metal layer deposited on at least one portion of the free surface of the conductive film,
the electrically insulating solid substrate having at least one polymer material, and
the metal layer having at least one metal,
said process comprising the following steps:
1) a step of preparing a liquid composition having at least one polymer material and at least one metal in the form of filiform nanoparticles, said liquid composition comprising from 0.2% to 10% by volume of said metal relative to the total volume of the liquid composition,
2) a step of applying the liquid composition from step 1) to at least one portion of the surface of said electrically insulating substrate,
3) a step of drying, and optionally of heat treatment, of the liquid composition in order to obtain an intermediate composite part having the electrically insulating solid substrate and the conductive film deposited on at least one portion of the surface of the substrate, said conductive film comprising said polymer material and from 1% to 10% by volume of said metal in the form of filiform nanoparticles relative to the total volume of the conductive film,
4) a step of electrodeposition of at least one metal on at least one portion of the free surface of the conductive film, in order to obtain said composite part.

2. The process as claimed in claim 1, wherein the electrically insulating solid substrate additionally has a reinforcing agent and/or conductive particles.

3. The process as claimed in claim 2, wherein the substrate has at most 10% by volume of conductive particles and/or reinforcing agent.

4. The process as claimed in claim 1, wherein the polymer material is a thermosetting polymer.

5. The process as claimed in claim 1, wherein the liquid composition from step 1) additionally has a metal identical to the metal but not being in the form of filiform nanoparticles.

6. The process as claimed in claim 1, wherein step 1) further comprises the following sub-steps:
1ₐ) a step of preparing a dispersion of at least one metal in the form of filiform nanoparticles in a solvent,
1_{b}) a step of mixing the dispersion from the preceding step 1ₐ) with at least one polymer material,
1_{c}) a step of homogenizing the mixture from the preceding step 1_{b}) in order to form a liquid composition comprising at least one polymer material and at least one metal in the form of filiform nanoparticles, said liquid composition comprising from 0.2% to 10% by volume of said metal relative to the total volume of the liquid composition.

7. The process as claimed in claim 6, wherein the solvent from step 1ₐ) is selected from the group consisting of hydrocarbon solvents, oxygenated solvents, chlorinated solvents, water and mixtures thereof.

8. The process as claimed in claim 1, wherein step 2) is carried out by spraying the liquid composition from step 1) onto at least one portion of the surface of said electrically insulating solid substrate, or with the aid of a brush, or else by immersing at least one portion of the surface of said electrically insulating solid substrate in the liquid composition from step 1).

9. The process as claimed in claim 1, wherein said process further comprises a step i), prior to step 2), of degreasing the substrate.

10. The process as claimed in claim 1, wherein the conductive film from step 3) comprises from 1% to 5% by volume of metal relative to the total volume of said conductive film.

11. The process as claimed in claim 5, wherein the conductive film obtained in step 3) is from 0.5% to 10% by volume of metal relative to the total volume of the conductive film.

12. The process as claimed in claim 1, wherein said process further comprises, between steps 3) and 4), a step ii) of sanding at least one portion of the free surface of the conductive film in order to adapt the surface finish before step 4).

13. The process as claimed in claim 1, wherein the metal is selected from the group consisting of Cu, Sn, Co, Fe, Pb, Ni, Cr, Au, Pd, Pt, Ag, Bi, Sb, Al, Li and mixtures thereof.

14. The process as claimed in claim 1, wherein said metal is a stainless metal.

15. A high-performance composite part that is electrically conductive at the surface having an electrically insulating solid substrate, a conductive film deposited on at least one portion of the surface of the electrically insulating substrate, and a metal layer deposited on at least one portion of the free surface of the conductive film, said part (CP₁) wherein:
the electrically insulating solid substrate has at least one polymer material,
the conductive film has at least one polymer material and at least one metal in the form of filiform nanoparticles, said conductive film having from 1% to 10% by volume of said metal relative to the total volume of the conductive film,
the metal layer has at least one metal, and
the substrate, the conductive film, the metal layer, the metal, the metal, the polymer material and the polymer material are as defined in claim 1.

16. A housing for an electrical and/or electronic component comprising:
a high-performance composite part that is electrically conductive at the surface as prepared as claimed in the process defined in claim 1.

17. An electrically insulating part having abrasion resistance, wear resistance and resistance to harsh atmospheric and/or chemical conditions, said electrically insulating part comprising:
a high-performance composite part that is electrically conductive at the surface as defined in claim 1.

18. An electrically insulating part that is resistant against electromagnetic radiation (electromagnetic shielding) and/or against electrostatic discharges, said electrically insulating part comprising:
a high-performance composite part that is electrically conductive at the surface as defined in claim 1.

19. A material having and improved surface electrical conductivity, said material comprising: a high-performance composite part that is electrically conductive at the surface as defined in claim 1.
